(19) United States
(12) Patent Application Publication
(10) Pub. No.: US 2007/0200142 A1
(43) Pub. Date: Aug. 30, 2007

(54) High linear enhancement-mode heterostructure field-effect transistor

(76) Inventors: Ching-Sung Lee, Taichung City (TW); Wei-Chou Hsu, Taichung City (TW); Jun-Chin Huang, Taichung City (TW); Chien-Hung Chen, Taichung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/360,444

(22) Filed: Feb. 24, 2006

(51) Int. Cl. H01L 31/00

(52) U.S. Cl. 257/192; 257/E29.188

(57) ABSTRACT

The present invention relates to a high linear enhancement-mode heterostructure field-effect transistor. More, the present invention uses an InGaAs channel structure with a linear change, and integrates an adjusting effect of working region corresponding to the threshold voltage of the element. It not only directly provides a complementary structure for the conventional depletion-mode element to select, but also increases the range of the gate voltage swing. More, some important characteristics, such as current driving capacity, transconductance gain, linear amplification, and high speed operation can be largely improved. More particularly, E-mode working element has a low static power. Further, the present invention also has a high stop frequency characteristic of the high speed element from the composite semiconductor, and it can be applied to the microwave push-pull amplification circuit.

### BACKGROUND OF THE INVENTION

The present invention relates to a high linear enhancement-mode (hereinafter referred to as “E-mode”) heterostructure field-effect transistor (hereinafter referred to as “FET”). More particularly, the high linear e-mode heterostructure field-effect structure has a channel with a linear change. By providing an e-mode field-effect element as well as using a channel with a linear change in the present invention, some important characteristics, such as high linearity, high transconductance, can be improved. Further, the structure of the present invention can be selected as a complementary working E-mode heterostructure FET for being a high linear E-mode heterostructure FET.

The channel structure in conventional heterostructure field-effect transistors often has different composites in each epitaxy layer. Therefore, the channel is formed with different transconductance speed and different carrier confinements. More, a conventional channel structure of the E-mode heterostructure FET uses a single channel with mimic structure. The channel even has high transconductance speed, but the composite of the semiconductor channel layer is limited by its single saturated speed. Therefore, the element can not obtain a well linearity.

The present invention uses a linear graded channel structure designed in heterostructure field-effect, also works with a gate electrode board having high working function and a Schottky gate contact layer having wide energy gap, and enhances a voltage threshold (VT) for obtaining a E-mode and excellent linearity characteristics. More particularly, the present invention can combine with depletion element structure for forming a complementary push-pull amplification configuration.

### SUMMARY OF THE INVENTION

The main object of the present invention is to overcome the above problems as well as to provide a high linear E-mode heterostructure FET. The structure of the present invention is a high electronic mobility transistor comprising high linear e-mode δ-doped AlGaAs, InGaAs or InP. The structure can directly provide a complementary structure selectable for the depletion working element, and increase the range of the gate voltage swing. More, it can largely increase current driving capacity, transconductance gain, linear amplification, and high speed operation as well as directly apply in the complementary microwave active amplification semiconductor field for high potential applications in the industry.

In order to achieve the above purpose, the structure of the present invention comprises:
a semiconductor substrate;
a buffer layer positioning on said substrate;
a InGaAs channel layer positioning on said buffer layer;
an insulating layer positioning on said channel layer; wherein In composition in said insulating layer side of said channel layer being higher than the one in said buffer layer side;
a δ-doped carrier supplier positioning on said insulating layer;
a Schottky gate contact layer positioning on said δ-doped carrier supplier;
a drain/source ohmic contact layer positioning on said Schottky gate contact layer; and
a gate electrode board positioning on said Schottky gate contact layer.

The present invention can be best understood through the following description and accompanying drawings wherein:

### BRIEF DESCRIPTION OF THE DRAWINGS

FIG. 1 shows a cross-sectional view of the structure in the present invention;

FIG. 2 shows an output characteristic curve of a high linear E-mode in the present invention.

### DETAILED DESCRIPTION OF THE PREFERRED EMBODIMENTS

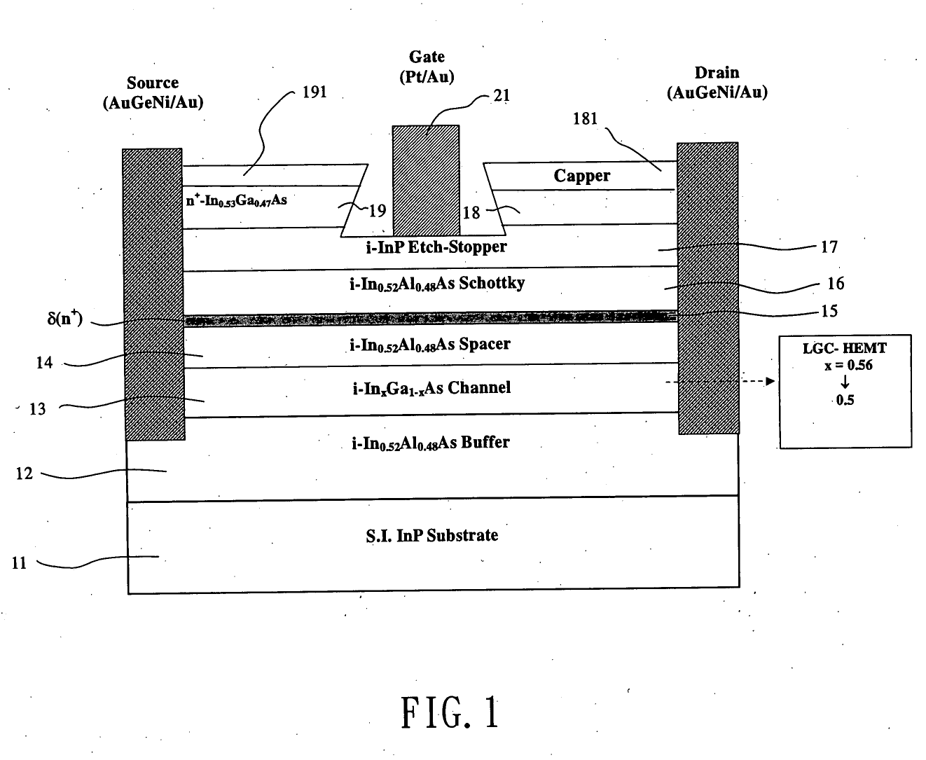

Please refer to FIG. 1. The embodiments from the figures are only used to illustrate the present invention, not intended to limit the scope thereof.

FIG. 1 is one of the preferred embodiments showing a high linear E-mode heterostructure FET. The semiconductor epitaxy structure of the transistor is grown by metal organic chemical vapor deposition (hereinafter referred to as “MOCVD”) or molecular beam epitaxy (hereinafter referred to as “MBE”). The epitaxy structure is that a In_{0.52}Al_{0.48}As buffer layer (12) with high energy barrier and wide band gap, a InₓGa₁₋ₓAs channel layer (13) with In linear step-graded type (x is at the range between 0.56 and 0.5), a In_{0.52}Al_{0.48}As insulating layer (14) with high energy barrier, a Si δ-doped carrier supplier (15), a Schottky gate contact layer (16) with In_{0.52}Al_{0.48}As, a selective InP etch stop layer (17), and N⁺ drain/source ohmic contact layers (18 and 19) with high doped In_{0.53}Ga_{0.47}As are grown on said InP semi-insulating substrate, respectively. A passivation layer (181 and 191) is formed on said drain and said source ohmic contact layers (18 and 19) individually for protecting the element.

In the preferred embodiments in the present invention, the substrate (11) can be one semi-insulating material selected from InP, GaAs or Al₂O₃. The buffer layer (12) can be InAlAs, GaAs, InP, InGaAs, AlGaAs, GaN or InGaN of high energy barrier semiconductor materials while corresponding to InGaAs channel layer (13). The insulating layer (14) can be un-doped InAlAs, GaAs, InP, InGaAs, AlGaAs, GaN or InGaN of high energy barrier semiconductor materials while corresponding to InGaAs channel layer (13). The InGaAs channel layer (13) can be either pure or doped In ternary/quaternary composites of semiconductor materials. The Schottky gate contact layer (16) can be un-doped InAlAs, GaAs, InP, AlInAsSb, AlGaAs, AlGaN of high energy barrier semiconductor materials while corresponding to InGaAs channel layer (13). The drain/source ohmic contact layers (18 and 19) can be one N type semiconductor material selected from high doped InAlAs, GaAs, InP, InGaAs, AlGaAs, GaN or InGaN.

More, the preferred embodiments first use wet etching or isotropic ion etching to form an insulated island. After photo-etching technique is defined, a deeper interface between drain/source regions is formed, and GeAu/Ni/Au alloy electrode board is deposited, quenching treatment temperature is controlled for forming an ohmic contact between alloy and channel as shown in the drain/source electrode structure of FIG. 1. Then, the photo-etching technique is to define the gate region for processing further gate recess etching manufacture, which comprises: a selected etching processing until to the interface of selective InP etch stop layer (17)/InAlAs Schottky gate contact layer (16); a second etching processing on selective InP etch stop layer (17); and further depositing gate electrode board (21) with high working function Pt/Au alloy material on the InAlAs Schottky gate contact layer (16) for enhancing voltage threshold of the element. The gate electrode board (21) can be one alloy material with high working function selected from Pt/Au, Ti/Au, and Mo/Au.

Since InAlAs buffer layer (12) has high energy barrier and wide band gap characteristics, the current leakage of the substrate (11) can be largely decreased for improving the stop characteristic of the filed-effect transistor. More, InAlAs buffer layer (12) and InAlAs insulating layer (14), and InGaAs channel layer (13) can form a quantum well structure as well as provide a depletion capacity for the electronic group in the channel. Further, it can efficiently improve the transconductance gain for the element and increase the current driving capacity. More particularly, InAlAs buffer layer (12) is designed on the upper side of InₓGa₁₋ₓAs linear graded channel layer (13). By using SiH₄ as a high doped material in N+ δ-doped carrier supplier (15), the concentration of a two-dimensional electron gas (hereinafter referred to as “2DEG”) in InGaAs channel layer (13) is increased, and the current driving capacity is strengthen. The material of the gate electrode board (21) can be selected from some materials with high working function, such as, vapor deposited Pt/Au, Ti/Au, and Mo/Au. While the alloy materials are deposited on InAlAs Schottky gate contact layer (16) having wide band gap, the energy barrier of Schottky gate contact layer and the voltage threshold of the element can be increased. Therefore, when the gate of the element is at zero voltage swing, high Schottky contact voltage can appear on 2DEG in depletion InGaAs channel layer (13). More, the element in the stop region can obtain e-mode working characteristic.

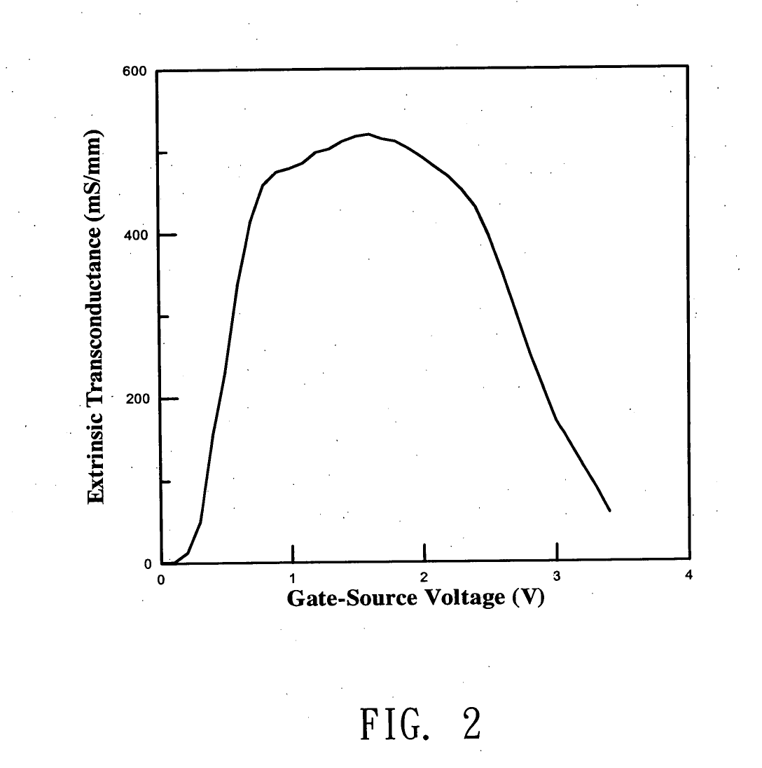

One main feature of high linear e-mode working characteristic in the present invention is InGaAs channel layer (13) showing a linear graded type (x is at the range between 0.56 and 0.5). In the conventional single channel structure, the original stop channel layer is opened by an increased gate voltage swing, and electro gas is gradually closed to the end of the gate. Therefore, when the distance between 2DEG and gate is decreased, Coulomic scattering effect is increased, and electronic transconductance is decreased. More, when In of InGaAs channel layer (13) in the present invention showing a linear graded type (x is at the range between 0.56 and 0.5) is closed to the end of the gate (21), the carrier conductance is enhanced by an increased In composite. Further, InGaAs semiconductor with high In composites has higher electronic saturated speed and transconductance. Therefore, when 2DEG is closed to the end of the gate by an increased voltage swing of the gate, the transconductance is enhanced against Coulomic scattering effect. Please refer to FIG. 2, and it has an e-mode operation and a high linearity. More, the range of gate voltage swing is largely increased, and the transconductance gain also remains at a high value with plateau.

The present invention uses an InₓGa₁₋ₓAs channel structure with a linear change, and integrates an adjusting effect of working region corresponding to the threshold voltage of the element. It not only directly provides a complementary structure for the conventional depletion-mode element to select, but also increases the range of the gate voltage swing. More, some important characteristics, such as current driving capacity, transconductance gain, linear amplification, and high speed operation can be largely improved. More particularly, E-mode working element has a low static power. Further, the present invention also has a high stop frequency characteristic of the high speed element from the composite semiconductor, and it can be applied to the microwave push-pull amplification circuit. More, it can be directly applied to the complementary microwave active amplification semiconductor technique, which has a high potential using in the industry.

While the invention has been described with reference to preferred embodiments, it will be understood by those skilled in the art that various changes may be made and equivalents may be substituted for members thereof without departing from the scope of the invention. In addition, many modifications may be made to adapt a particular situation to the teachings of the invention without departing from the essential scope thereof.

What is claimed is:

1. A high linear enhancement-mode (E-mode) heterostructure field-effect transistor (FET), comprising:
a semiconductor substrate;
a buffer layer positioning on said substrate;
a InGaAs channel layer positioning on said buffer layer;
an insulating layer positioning on said channel layer; wherein In composition in said insulating layer side of said channel layer being higher than the one in said buffer layer side;
a δ-doped carrier supplier positioning on said insulating layer;
a Schottky gate contact layer positioning on said δ-doped carrier supplier;
a drain/source ohmic contact layer positioning on said Schottky gate contact layer; and
a gate electrode board positioning on said Schottky gate contact layer.

2. A high linear E-mode heterostructure FET according to claim 1, wherein the material of said substrate can be one selected from InP, GaAs or Al₂O₃ of semi-insulating materials.

3. A high linear E-mode heterostructure FET according to claim 1, wherein said buffer layer can be InAlAs, GaAs, InP, InGaAs, AlGaAs, GaN or InGaN of high energy barrier semiconductor materials while corresponding to InGaAs channel layer.

4. A high linear E-mode heterostructure FET according to claim 1, wherein said insulating layer can be un-doped InAlAs, GaAs, InP, InGaAs, AlGaAs, GaN or InGaN of high energy barrier semiconductor materials while corresponding to InGaAs channel layer.

5. A high linear E-mode heterostructure FET according to claim 1, wherein the structure of said channel layer comprises In composite and a linear step-graded type.

6. A high linear E-mode hetero-structure FET according to claim 5, wherein said channel layer can be either pure or doped In ternary/quaternary composites of semiconductor materials.

7. A high linear E-mode heterostructure FET according to claim 1, wherein said Schottky gate contact layer can be un-doped InAlAs, GaAs, InP, AlInAsSb, AlGaAs, AlGaN of high energy barrier semiconductor materials while corresponding to InGaAs channel layer.

8. A high linear E-mode heterostructure FET according to claim 1, wherein said drain/source ohmic contact layer can be one N type semiconductor material selected from high doped InAlAs, GaAs, InP, InGaAs, AlGaAs, GaN or InGaN.

9. A high linear E-mode heterostructure FET according to claim 1, wherein said gate electrode board can be one alloy material with high working function selected from Pt/Au, Ti/Au, and Mo/Au.

10. A high linear E-mode heterostructure FET according to claim 1, wherein a passivation layer is formed on said drain and said source ohmic contact layers individually for protecting the element.

11. A high linear E-mode heterostructure FET according to claim 1, wherein a selective InP etch stop layer is formed on said Schottky gate contact layer, and said gate electrode board and said drain/source ohmic contact layer are formed on said selective InP etch stop layer.

12. A high linear E-mode heterostructure FET according to claim 1, wherein the semiconductor epitaxy structure of said transistor is grown by MOCVD or MBE.
